(19) United States
(12) Patent Application Publication
(10) Pub. No.: US 2026/0195497 A1
(43) Pub. Date: Jul. 9, 2026

(54) SYSTEM AND METHOD FOR DETERMINING SPRAY CHARACTERISTICS

(71) Applicant: MAZLITE INC., Toronto (CA)

(72) Inventors: Khalil SIDAWI, Cambridge (CA); Amirreza AMIGHI, Toronto (CA); Cameron DALLAS, New Westminster (CA)

(21) Appl. No.: 19/009,231

(22) Filed: Jan. 3, 2025

Related U.S. Application Data
(63) Continuation of application No. PCT/CA2023/050911, filed on Jul. 6, 2023.
(60) Provisional application No. 63/367,797, filed on Jul. 6, 2022.

(51) Int. Cl. G06F 30/20

(52) U.S. Cl. CPC G06F 30/20

(57) ABSTRACT

There is provided a system and method for determining spray characteristics of a powder or liquid spray. The method including: receiving spray characteristics of the powder or liquid spray; generating a spray map comprising correlating the received spray characteristics to spray application characteristics, operational parameters of a spray apparatus, or both, the correlations determined using a calibration of the scanning measurements; and outputting the spray map. In a particular case, the method further including adjusting operational parameters of the spray apparatus to achieve a specific performance of application of the spray using the spray map.

### TECHNICAL FIELD

The following relates generally to powder or liquid spray apparatuses; and more specifically, to a system and method for determining spray characteristics of a powder or liquid spray.

### BACKGROUND

Spray nozzles have numerous applications, such as in spray cooling systems, coating devices, irrigation and pesticide application in agriculture industry, and in fuel injection systems of most engines. Sprays formed by a spray nozzle are characterized by the size and spatial distributions of the droplets, which depend on nozzle geometry, fluid properties, and operational settings such as fluid flow rates and pressures. In an example, in an automotive painting application, film thickness of paint sprayed on a surface is a function of, for example, the spray's droplet size, spray pattern or geometry (number of droplets flying through a unit area per second), overlap distance, number of passes, and robot speed. Tolerances on the film thickness are very tight, as thick films can result in defects and unnecessary added costs (due to more paint usage). SUMMARY

In an aspect, there is provided a processor-executable method for determining spray characteristics of a powder or liquid spray, the method comprising: receiving spray characteristics of the powder or liquid spray; generating a spray map comprising correlating the received spray characteristics to spray application characteristics, operational parameters of a spray apparatus, or both, the correlations determined using a calibration of the scanning measurements; and outputting the spray map.

In a particular case of the method, the method further comprising adjusting operational parameters of the spray apparatus to achieve a specific performance of application of the spray using the spray map.

In another case of the method, the spray characteristics comprise one or more of droplet size, droplet distribution, droplet velocity, and spray pattern or geometry.

In yet another case of the method, the operational parameters comprise one or more of bell speed, flow rate, shaping air flow rates, and electrostatic charges.

In yet another case of the method, the scanning measurements are conducted at several distinct positions.

In yet another case of the method, the spray apparatus is moved radially, and wherein generating the spray map comprises determining the spatial position of each droplet as a function of the spray radius using a time at which each captured scan was performed.

In yet another case of the method, the calibration comprises changing, one or more operational parameters and determining effects on the spray characteristics using the scanning measurements.

In yet another case of the method, the spray map is generated using a model to correlate the spray characteristics to the operational parameters.

In yet another case of the method, generating the spray map comprises correlating spray characteristics to changes in operational parameters, and correlating changes in spray characteristics to spray application characteristics.

In yet another case of the method, the spray application characteristics comprise one or more of color, film build, film appearance and quality, evaporation, powder morphology, and transfer efficiency.

In another aspect, there is provided a system for determining spray characteristics of a powder or liquid spray, the system comprising one or more processors in communication with a data memory to execute: a scanning module to receiving spray characteristics of the powder or liquid spray; and a mapping module to generate a spray map comprising correlating the received spray characteristics to spray application characteristics, operational parameters of a spray apparatus, or both, the correlations determined using a calibration of the scanning measurements, and to output the spray map.

In a particular case of the system, the system further comprising an adjustment module to adjust operational parameters of the spray apparatus to achieve a specific performance of application of the spray using the spray map.

In another case of the system, the spray characteristics comprise one or more of droplet size, droplet distribution, droplet velocity, and spray pattern or geometry.

In yet another case of the system, the operational parameters comprise one or more of bell speed, flow rate, shaping air flow rates, and electrostatic charges.

In yet another case of the system, the scanning measurements are conducted at several distinct positions.

In yet another case of the system, the spray apparatus is moved radially, and wherein generating the spray map comprises determining the spatial position of each droplet as a function of the spray radius using a time at which each captured scan was performed.

In yet another case of the system, the calibration comprises changing, one or more operational parameters and determining effects on the spray characteristics using the scanning measurements.

In yet another case of the system, the spray map is generated using a model to correlate the spray characteristics to the operational parameters.

In yet another case of the system, generating the spray map comprises correlating spray characteristics to changes in operational parameters, and correlating changes in spray characteristics to spray application characteristics.

In yet another case of the system, the spray application characteristics comprise one or more of color, film build, film appearance and quality, evaporation, powder morphology, and transfer efficiency.

These and other aspects are contemplated and described herein. It will be appreciated that the foregoing summary sets out representative aspects of systems and methods to assist skilled readers in understanding the following detailed description.

### BRIEF DESCRIPTION OF THE DRAWINGS

The features of the invention will become more apparent in the following detailed description in which reference is made to the appended drawings wherein:

FIG. 1 is schematic diagram of a system for determining spray characteristics of a powder or liquid spray, according to an embodiment;

FIG. 2 is flowchart for a method for determining spray characteristics of a powder or liquid spray, according to an embodiment;

FIG. 3 is an example simplified path of an atomizer covering a flat surface in a series of passes;

FIG. 4 is a chart showing an example of liquid volume fraction as a function of the distance from the center axis of the spray captured during an experiment;

FIG. 5 is a chart showing an example of a theoretical and an experimental film thickness for an atomizer travelling over a vertical surface;

FIG. 6 is a chart of microns to flop and bell speed to illustrate an example of how a spray map ensures that paint application is within specifications;

FIG. 7 shows color vector, ΔE, versus the Sauter mean diameter (D₃₂) of a metallic paint as measured in example experiments for an atomizer operating at several bell speeds;

FIG. 8 is schematic diagram of an imaging device for fast-moving particle characterization;

FIG. 9 is schematic diagram of a lighting module;

FIG. 10 is perspective view of a housing;

FIG. 11 is perspective view of a front-end piece for the housing of FIG. 10;

FIG. 12 is schematic diagram of an image analysis module;

FIG. 13 is a flowchart for a method for fast-moving particle characterization, according to an embodiment;

FIG. 14 is schematic of an example opto-isolator;

FIG. 15 shows various example triggering modes;

FIG. 16 illustrates a cutaway view of an example of a camera probe;

FIG. 17 illustrates a cutaway view of an example of a laser probe;

FIG. 18 is a chart of experimental results for a normalized volume of a spray, consisting of solids dissolved in a solvent, at several axial distances from a nozzle.

### DETAILED DESCRIPTION

Embodiments will now be described with reference to the figures. For simplicity and clarity of illustration, where considered appropriate, reference numerals may be repeated among the Figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, well-known methods, procedures and components have not been described in detail so as not to obscure the embodiments described herein. Also, the description is not to be considered as limiting the scope of the embodiments described herein.

Various terms used throughout the present description may be read and understood as follows, unless the context indicates otherwise: “or” as used throughout is inclusive, as though written “and/or”; singular articles and pronouns as used throughout include their plural forms, and vice versa; similarly, gendered pronouns include their counterpart pronouns so that pronouns should not be understood as limiting anything described herein to use, implementation, performance, etc. by a single gender; “exemplary” should be understood as “illustrative” or “exemplifying” and not necessarily as “preferred” over other embodiments. Further definitions for terms may be set out herein; these may apply to prior and subsequent instances of those terms, as will be understood from a reading of the present description.

Any module, unit, component, server, computer, terminal, engine or device exemplified herein that executes instructions may include or otherwise have access to computer readable media such as storage media, computer storage media, or data storage devices (removable and/or non-removable) such as, for example, magnetic disks, optical disks, or tape. Computer storage media may include volatile and non-volatile, removable and non-removable media implemented in any method or technology for storage of information, such as computer readable instructions, data structures, program modules, or other data. Examples of computer storage media include RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by an application, module, or both. Any such computer storage media may be part of the device or accessible or connectable thereto. Further, unless the context clearly indicates otherwise, any processor or controller set out herein may be implemented as a singular processor or as a plurality of processors. The plurality of processors may be arrayed or distributed, and any processing function referred to herein may be carried out by one or by a plurality of processors, even though a single processor may be exemplified. Any method, application or module herein described may be implemented using computer readable/executable instructions that may be stored or otherwise held by such computer readable media and executed by the one or more processors.

The following relates generally to powder or liquid spray apparatuses; and more specifically, to a system and method for determining spray characteristics of a powder or liquid spray.

While the present disclosure generally refers to application of spraying paint with a spray applicator, it is understood that the present embodiments can be used with any suitable powder or liquid spray application, for example, paint, evaporative cooling, combustion, or the like.

In an example application, pharmaceutical sprays are composed of liquid made up from a solvent and dissolved solids. Ideally, the solvent evaporates during the spray-drying process and only spherical, monodisperse, hollow, porous particles remain. A particle is established when the concentration of solids at the droplet surface reaches a predetermined critical level. It is desirable for the solids to form a spherical shell that is able to maintain its structure because the particle's size and morphology will have a direct effect on the spray-dried product's performance. Current approaches used to predict the droplet size generally lack the ability to capture the viscoelastic behavior of polymeric spray solutions used in pharmaceutical applications. Advantageously, using the embodiments described herein, generating a droplet size distribution that results in the optimal particle size and morphology can substantially improve production capacity and compound performance.

In a particular example, automotive paints are applied using electrostatic rotating bell atomizers, which operate by using the centrifugal force to drive a thin paint film over the bell-cup's inner surface towards its edge, and the paint sheet breaks-up into a cloud of droplets after it is expelled. Air jets and electrostatic forces are used to direct paint onto the target surface. Robot manipulators are used to position the paint atomizers. It can take three to five months of trial-and-error to determine which robot path minimizes paint, cycle time, and material waste while depositing a film with acceptable uniformity. There are some general efforts to automate the robot path by simulating the paint application process to reduce the cost and time of bringing a new automobile to market.

The paint shop can be the biggest source of regulated chemicals including VOCs (~35 g/m2 of coated car surface) and other air pollutants (CO2,eq production is ~0.5 tonne/unit); over 80% of all environmental concerns in automobile assembly are related to painting processes. The cost of abatement equipment to capture these emissions and dispose of hazardous waste material is very significant. Despite this, the painting process is highly inefficient. The transfer efficiency, i.e., the fraction of paint sprayed that adheres to a surface, is only about 40% for car bodies and as low as 10% for small parts. Improvements in transfer efficiency can significantly reduce emissions and energy use. With these challenges in mind, embodiments of the present disclosure can advantageously be used to reduce VOC emissions, improve transfer efficiencies, and minimize re-work of painted parts.

In some approaches, to determine film thickness of paint sprayed by a spray nozzle, a regression model can be used that correlates a test matrix of operational parameters to measured film builds; however, this is both time consuming and costly. In such cases, an atomizer sprays on a ‘scanner’ that measures the resultant film build. This technique is limited in that it lacks direct measurements of the spray in real-time, so spray characteristics on, for example, a manufacturing line may not be captured.

In another common approach, transfer efficiency of the sprayed paint on a surface to be sprayed is determined by weighing a sample after it was sprayed to calculate how much paint is on the surface relative to the amount sprayed. In some cases, while increasing electrostatic charge is meant to solve this issue, this can result in robots shorting, and further atomization of the liquid (very small droplets lack the momentum necessary to impinge on the surface).

The size of paint droplets impinging on a surface affects the color and flop (a measure of the change in lightness at different observation angles) of the film. In some approaches, laser based devices that rely on reflections can be used to get droplet size measurements. However, metallic flakes inside rotating paint droplets would disrupt this signal, making it very difficult to accurately measure droplet size of paint sprays.

Many process inputs can cause the spray characteristics to shift and mar the sprayed paint film. Attempting to control multiple process inputs (such as humidity, paint composition, temperature, downdraft velocity, and the like) is prone to errors due to the compounding uncertainty on each parameter. In the present embodiments, by determining spray characteristics, e.g., droplet size and spray pattern or geometry, accurate control parameters of the spray can be used.

In some current approaches, trial and error on the manufacturing line is used to determine if a specific paint should be sprayed wet (impinging droplets have a higher solvent content) or dry (lower solvent content).

There are various approaches to measure particle size distributions using a variety of techniques. For example, diffraction-based methods, phase doppler methods, and direct imaging approaches. However, generally, prior direct imaging approaches are only capable of operating in research and development environments and do not meet the full requirements of operating in Hazardous Locations. Due to the size of a laser system, high speed camera, and optics, each of these components must be placed in the working environment separately. Then the camera and laser must be aligned. The alignment is usually a long process that must be re-performed often as the components will drift slightly over time, the location of the work being done will move, or other devices in the working environment will accidentally hit the equipment.

Additionally, generally other approaches to particle sizing do not meet the minimum requirement to operate in Hazardous Locations, and therefore cannot operate in many industrial environments where sprays are used.

Additionally, current droplet measurement techniques generally do not instruct the user how the droplet measurements are connected to the final color or paint quality (for example, in the automotive painting industry); which is left as an exercise for the user. Additionally, there is no framework or process for the user to apply the measurement data to solve their painting problems.

Other approaches for spray pattern or geometry measurement have instruments that give information on how the spray is distributed in space. They generally do not give droplet size information. While these approaches can potentially help with film thickness estimates, they do not measure the droplet size; and thus, do not give the user any information about evaporation, colour, or potential surface defects.

Generally, the current approaches suffer from at least the problems of inconsistent film thickness, low transfer efficiency, inconsistent color match between parts, surface defects due to bad spray quality, and overall higher volatile organic compounds and greenhouse gas emissions due to errors.

In some cases, images of the fluid being ejected from the edge of the cup can give a qualitative determination of the quality of the spray (for example, unclean cups, plugged serrations, or the like). While this can provide a good estimate of the droplet size distribution, it generally does not fully represent the actual droplet size that would impact the surface, nor the spray pattern or geometry (which is of large industrial interest); as there may be some spatial variation that can impact the film build. Additionally, this approach may have to contend with unclean cups, plugged serrations, or the like.

The present embodiments can advantageously extract a spray pattern or geometry from captured images using images captured radially across a spray at the tip-to-part distance. The relative frequency of droplets in images at various radial positions can be used to obtain a spray pattern or geometry, and generate a flux spray map of the spray; in real-time on a manufacturing line.

In some cases, for each paint, spray maps can be determined that correlate spray characteristics, e.g., droplet size and spray pattern or geometry, with color and film build, and can be used to predict if the paint finish and color will be within manufacturer specified tolerances. Furthermore, if the spray is not of sufficient quality, the present embodiments can be used to recommend corrective actions for the paint operator. Advantageously, these corrective actions can save a lot of time required for paint testing and reduce paint wastage and emissions. Being able to constantly monitor the spray characteristics, e.g., droplet size and spray pattern or geometry, on an assembly line allows the paint operator to ensure that the paint spray is within specification; if the paint spray is not, they can do preventative maintenance before a defect arises.

The present inventors have determined through experimentation that the spray characteristics, e.g., droplet size and spray pattern or geometry, provide accurate characterizing of the powder or liquid spray application, for example, film appearance and quality. Using the spray maps and predictive models for film build of the present embodiments means that paint operators do not need to spend excessive time trying to find the best operational parameters that give a color match required by the OEM or the speed and overlap required to match the film thickness. Generally, even though paint manufacturers provide recommended settings for the operational parameters of an atomizer, environmental factors (such as humidity and temperature) can impact the paint skewing the expected result. Advantageously, the paint operator can be notified if the spray characteristics do not match recommended specifications as per a spray map. This would ensure that painting does not continue as the coating (e.g., color) would be out of spec.

While the present disclosure generally refers to spray painting applications, it is to be understood by a person skilled in the art that determinations of spray characteristics can be applied to any suitable application. In a non-limiting example, the system can also be applied to pharmaceutical applications where spray characteristics, e.g., droplet size, directly affects the particle size; which can be a critical process parameter.

In the application of automotive paint, such paint is solvent-borne and is predominantly composed of solvent which evaporates during spraying and film settling. The rheology of impinging droplets will dictate how the paint film forms on the surface, and thus the color. However, knowing droplet rheology at impact is complicated by droplet evaporation during transport, which can increase due to the electrostatic charge. An advantage of the presently described system is that it can measure this evaporation rate (which is unique to each paint and affected by environmental conditions). Feedback is provided to paint operators if the droplet size is not within a given specification. By being constantly aware of droplet rheology, paint operators would not have to use trial and error to figure out if a specific paint should be sprayed wet (film has a higher solvent content) or dry (lower solvent content). Additionally, by ensuring droplet rheology at impact is within specification, while maintaining film quality, solvent-borne paints can be manufactured with a lower solvent content. This would decrease VOC emissions; a limiting parameter in automotive production.

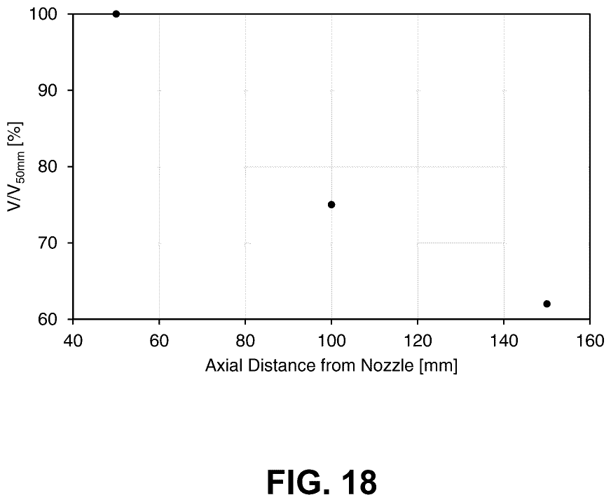

Additionally, measuring the velocity of droplets (which is a spray characteristic) gives the operator a timescale for the average time taken for the droplet to reach the part; and thus, the timescale for evaporation. FIG. 18 shows a chart of experimental results for a cumulative relative volume of a spray consisting of solids dissolved in a solvent at several axial distances from the nozzle. The volume is normalized by the volume at a distance of 50 mm. In FIG. 18, it can be clearly seen that evaporation causes the relative volume of the spray to decrease at distances further away from the nozzle.

In various current approaches, determining film thickness of sprayed paint would require that an operator spray a sample surface and then use a suitable device to measure the film build. This is both time consuming and costly, and only generates one data point. In other current approaches, the atomizer sprays a sample on a ‘scanner’ that measures the resultant film build. The present embodiments provide a substantially faster approach of predicting the film thickness on a surface from images captured of the spray, without the need to spray on sample panels or surfaces; and thus, avoids creating waste. Additionally, other information about the spray (such as film appearance and quality, colour, flop, transfer efficiency, evaporation, film thickness) can be obtained from these images.

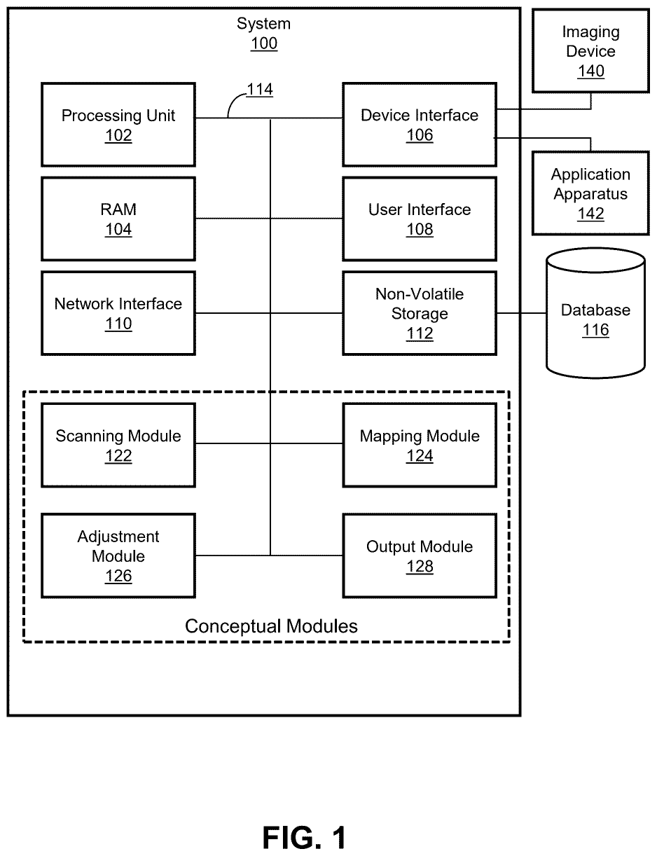

FIG. 1 shows various physical and logical components of an embodiment of a system for determining spray characteristics of a powder or liquid spray 100. As shown, the system 100 has a number of physical and logical components, including a processing unit 102 (comprising one or more processors), random access memory (“RAM”) 104, a device interface 106, a user interface 108, a network interface 110, non-volatile storage 112, and a local bus 114 enabling processing unit 102 to communicate with the other components. The processing unit 102 can execute or direct execution of various modules, as described below in greater detail. RAM 104 provides relatively responsive volatile storage to the processing unit 102. The user interface 108 enables an administrator or user to provide input via an input device, for example a keyboard and mouse, and to provide information to output devices, for example, a display. The device interface 106 can be used to communicate data from other devices, such as an imaging device 140 and/or an application apparatus 142. The network interface 110 permits communication with other systems, such as other computing devices and servers remotely located from the system 100, such as for a typical cloud-based access model. Non-volatile storage 112 stores the operating system and programs, including computer-executable instructions for implementing the operating system and modules, as well as any data used by these services. Additional stored data, as described below, can be stored in a database 116. During operation of the system 100, an operating system, the modules, and the related data may be retrieved from the non-volatile storage 112 and placed in RAM 104 to facilitate execution.

The system 100 includes one or more conceptual modules configured to be executed by the processing unit 102. In an embodiment, the modules include a scanning module 122, a mapping module 124, an adjustment module 126, and an output module 128. In some cases, some of the modules can be run at least partially on dedicated or separate hardware, while in other cases, at least some of the functions of some of the modules are executed on the processing unit 102.

The system 100 can be run on a computing device 26 and access content located on a server over a network, such as the internet, via the network interface 110. In further embodiments, the system 100 can be run only on the computing device or only on the server or run and/or distributed on any other computing device; for example, a desktop computer, a laptop computer, a smartphone, a tablet computer, a server, a smartwatch, distributed or cloud computing device(s), or the like. In some embodiments, the components of the system 100 are stored by and executed on a single computer system. In other embodiments, the components of the system 100 are distributed among two or more computer systems that may be locally or remotely distributed.

For the application of solvent-based paints, film thickness is tightly controlled due to the onset of surface tension driven flows in overly thick film layers, which leads to paint defects such as orange peel. Maintaining the appropriate thickness is a balance of several parameters, for example:
The local droplet flux of the atomizer;
The velocity of the atomizer;
The distance between passes (overlap); and
The number of overlaps.

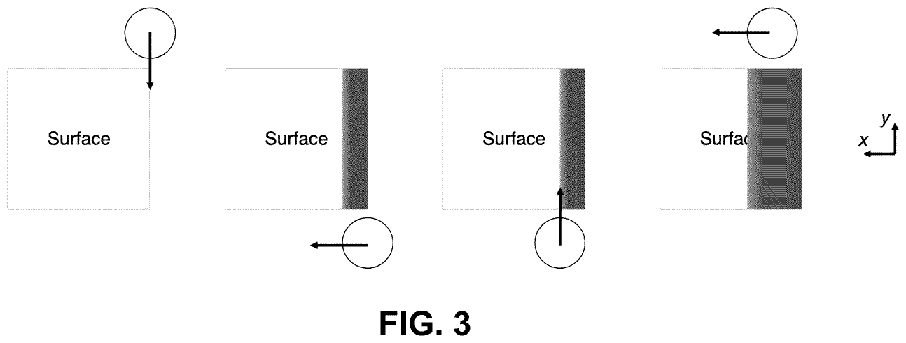

The schematic shown in FIG. 3 illustrates an example simplified path of an ESRB atomizer covering a flat surface in a series of passes.

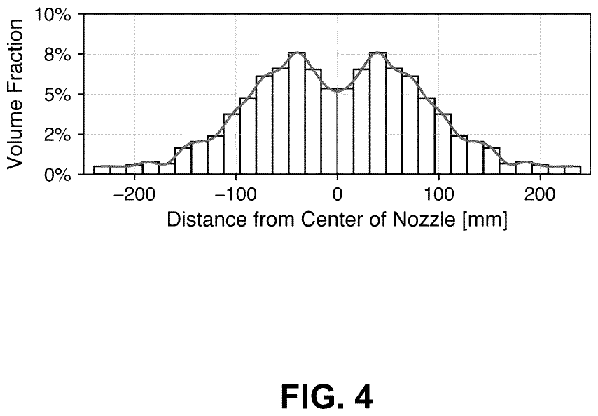

The film profile on a surface is determined by the spray characteristics. The spray pattern or geometry can be captured using the imaging device 140 to continuously capture images; for example, from a spray's center axis to its periphery. For this example, the relative abundance of droplets in images is then used to determine the volume fraction as a function of radial position. FIG. 4 shows an example of liquid volume fraction as a function of the distance from the center axis of the spray captured during an experiment.

In a particular case, assuming the spray is isotropic, the system 100 can interpolate the pattern to generate a film thickness profile given a tip velocity for the atomizer and the liquid flow rate.

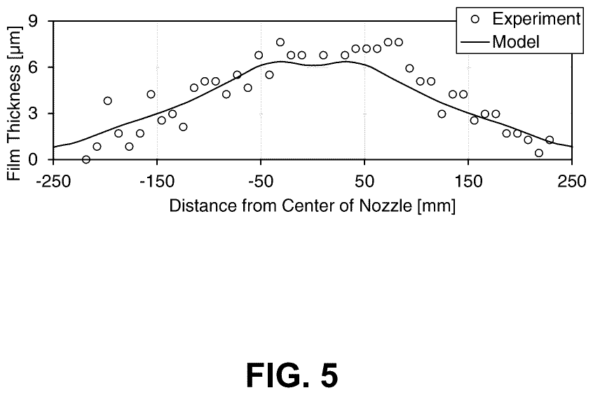

FIG. 5 shows an example of a theoretical and an experimental film thickness for an ESRB atomizer that is moving at a velocity (u) of 700 mm/s over a vertical surface. As evidenced by the experiments, the model shows good agreement with experimental results. The system 100 is able to identify regions where the film thickness would vary significantly, and thus, recommend if the overlap distance is too large. In some cases, a large overlap distance would generally result in a wavy film layer. In a particular case, the optimal overlap distance can be determined by plotting a horizontal line of regression through the maximum values of the film thickness profile. Generally, the film is wavy and not uniform if the standard deviation of the maximum values relative to the line of regression is large.

Generally, not all droplets have the momentum necessary to impinge on a surface. Droplets whose diameter falls below a penetration threshold would not be able to penetrate the boundary layer, and do not contribute to the film build. The volume ratio of droplets impinging on the surface is relative to the total value is defined as the transfer efficiency. Transfer efficiency of a spray generally varies based on specific operational parameter values, while also ensuring color match. Improving the transfer efficiency reduces the amount of paint being used, thus reducing cost and decreases VOC emissions.

In some cases, the theoretical film build can be determined assuming droplets smaller than a predetermined cutoff diameter lack the momentum to land on the surface. If the diameter cutoff is low, (i.e., only droplets that are less than, for example, 5 μm do not impinge) then the film would be thicker as more droplets make it to the surface; whereas if the diameter cutoff is high (i.e., droplets that are less than, for example, 20 μm do not impinge), then the film would be thinner and smaller droplets would end up in the overspray. The volume ratio of droplets above the cutoff diameter to the total number of droplets is, by definition, the transfer efficiency.

The film appearance (which can include color) applied using a spray is not only a function of the paint's pigments, but also of spray characteristics and film build. Unfortunately, many factors may affect the final color of a coating; for example, bell speed, electrostatic charge of the bell cup, temperature, humidity, and the like. By determining select process parameters the system 100 can determine control parameters of the spray system, in a particular case, the system 100 determines spray characteristics of droplet size and spray pattern or geometry.

The color of paint film is generally directly related to a function of the spray characteristic; e.g., droplet size. A particular metric to monitor is flop, which is a change in lightness of a paint film when viewed from different angles. In an example, color can be measured on painted panels and then these measurements can be received by the system. The received measurements can be combined with measurements of the spray characteristics to generate spray maps, as described herein. The spray maps model the flop as a function of the spray characteristics. The equation for flop is based on lightness values measured at specific angles relative to the specular reflection, for example:

$$Flop = 2.69 \frac{{( {L}_{15 °} - {L}_{110 °} )}^{1.11}}{{L}_{45 °}^{0.86}}$$

Aluminum flakes contained in many metallic paints act as tiny mirrors and reflect light back. The brightness caused by this reflection is greatest when viewing at the angle of reflection (based on the angle of incidence). However, the orientation of flakes in a thick film may not always be the same in several paint films.

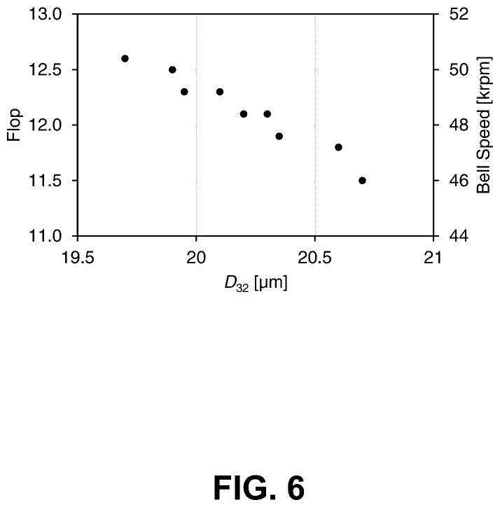

In an example, the droplet size can be correlated to color using regression analysis. FIG. 6 illustrates an example of how the spray map ensures that paint application is within specifications. For this example, a single independent variable (bell speed set to 46 RPM) is considered and the flop is specified to be greater than 12. The mean droplet size is represented by D₃₂, but the paint map is not limited to using this statistic. At the application environment (such as at a manufacturing line), instead of having the operator spray a part to check if the spray generates the desired color (as is current typical practice), the operators can make measurements of the spray and use the present system to analyze the measurements. Using such measurements, the spray map can be determined to recommend a change in the operational parameters in order to, for example, stay within specifications. In the example of FIG. 6, a 5% increase in the bell speed is recommended to decrease D32 from 20.6 μm to 20.3 8 μm to ensure the flop is within tolerance (i.e. greater than 12).

Another metric to monitor is a color vector (ΔE) based on lightness, hue and chromaticity measurements received by the system. The equation for the color vector is:

$$Δ {E}_{ab} = \sqrt{Δ {L}^{2} + Δ {a}^{2} + Δ {b}^{2}}$$

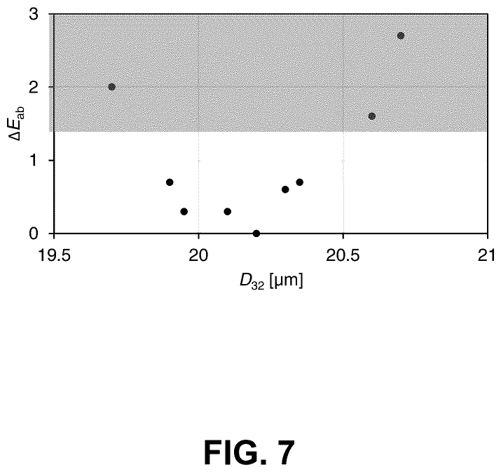

FIG. 7 shows ΔE versus the Sauter mean diameter (D₃₂) of a metallic paint as measured in example experiments for an atomizer operating at several bell speeds. A shaded background overlays ΔE values greater than 1.5, as that is near the level discernible by the human eye. There is a clear correlation between the ΔE and Sauter mean diameter. An increase or decrease in the droplet size from 20.2 μm causes the color to shift. This color shift becomes observable by a human observer when the Sauter mean diameter shifts by as little as ~0.4 μm.

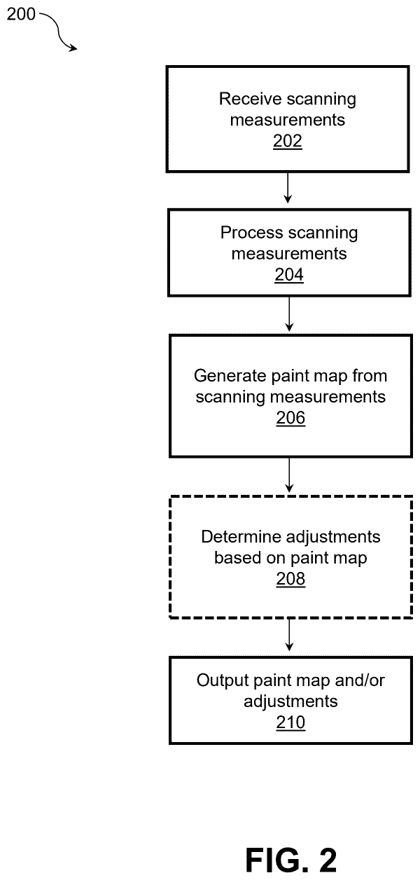

FIG. 2 illustrates a flowchart of a method for determining spray characteristics of a powder or liquid spray, in accordance with an embodiment. For ease of illustration, the method 200 is described with respect to determining film thickness on a simple flat surface; however, as understood by a person of skill in the art, the method 200 can be applied to more complex surfaces.

At block 202, the scanning module 122 performs, via the imaging device 140, scan to determine measurements of spray characteristics, such as droplet size, droplet distribution, droplet velocity, and/or spray pattern or geometry, at various operational parameters for a given paint and sprayer apparatus combination. In further cases, the scanning module 122 can receive the scan measurements from the database 116, the network interface 110 or the user interface 108. The operational parameters can include, for example, bell speed, liquid or powder flow rate, shaping air flow rates, and electrostatic charges. Scan measurements can refer to measurements taken at several positions, such as, several radial positions each at some axial distance away from the application apparatus 142 (for example, a bell-cup of the ESRB atomizer or a spray nozzle or a nozzle sprayer). In the example of the bell-cup, the bell-cup can be moved radially at a certain velocity with the imaging device 140 capturing images at a certain framerate to generate the scan measurements.

At block 204, the scanning module 122 can process the captured images/scans such that each measured droplet diameter can be associated with a spatial position. In some cases, this can be performed on a production line to ensure that the spray meets specifications in real-time.

To obtain the spatial position of each droplet in the spray, scan measurements can be conducted. In a particular approach, the atomizer can be moved towards the device; where the first images are of the periphery of the spray and the last image is of the spray's center. In this case, the atomizer is positioned some axial distance above the device (upstream). The scan width, being the distance from an initial position at the periphery to the center, can be received, and since the time at which each captured image is known, the position of each droplet as a function of the spray radius can be determined.

At block 206, the mapping module 124 generates a spray map using the scan measurements. The spray map comprises a dataset that comprises a set of correlations between the measured droplet size and spray pattern or geometry and spray application characteristics (for example, color, flop, film build, film appearance and quality, evaporation, powder morphology, and transfer efficiency). The spray map can be used to ensure that each applied paint spray is within a given specification. The spray map can be determined before a paint is largely deployed, for example, on a production line. The spray maps will generally be unique for each paint and will correlate droplet size and spray pattern or geometry to resultant color information for different operational parameters of the spraying apparatus 142. The operational parameters can include, for example, bell speed, liquid flow rate, shaping air flow rates, and electrostatic charges.

The correlations of the spray map can be determined using a calibration; for example, using half-factorial experimentation. During such calibration, one, or a combination, of operational parameters can be changed and the associated effects (i.e., correlation) on droplet size and spray pattern or geometry can be determined using the received scan measurements. In this way, getting the scan measurements of droplet size and/or spray pattern or geometry allows the system 100 to determine the flux of the spray and then store a correlation mapping of the scan measurements to the characteristics of application of the spray to the surface (such as film thickness and coverage). Additionally, knowledge of the correlation between the scan measurements and the operational parameters allows the system 100 to map how changes in the operational parameters effect droplet size and spray pattern or geometry, and thus, allow very accurate interpolation of how such parameters ultimately effect spray deposition on the surface.

Calibration of the spray map can be performed using an experiment (such as a box-behnken) to capture the variation in critical process parameters that emerge when operational parameters are changed. The color, film build, film appearance and quality, evaporation, powder morphology, and/or transfer efficiency will generally be correlated to the droplet size and spray pattern or geometry; which in turn will generally be correlated to the operational parameters. One example approach to correlate all these parameters is to use multivariate analysis, where a new paint map can be created for each paint.

In a particular case, the data structure of each spray map will consist of coefficients correlating the effect of operational parameters to the spray characteristics (droplet size, droplet distribution, droplet velocity, and spray pattern or geometry). One approach to model the effect of operational parameters is to use a regression model:

$$Y = {β}_{0} + {\sum }_{i = 1}^{n} {β}_{i} {X}_{i}$$

where Y represents one output, such as D32; β₀ and β₁, are regression coefficients; and X are the operational parameters. This system of linear equations can be solved based on the number of trials used in experiments. While the above is a regression model, other models can be used to capture interactions between operational parameters or a higher-order trend; such as other machine learning or artificial intelligence models.

In some cases, spray application characteristics, such as color, film build, film appearance and quality, evaporation, powder morphology, and/or transfer efficiency, can be identified and correlated to spray characteristics rather than the corresponding operational parameters. This can be done to avoid being affected by variations in process parameters; such as differences in environmental factors (e.g., humidity, temperature, and the like) between a paint manufacturer's facility and the application environment of the paint (e.g., an automotive manufacturing line). In such cases, operational parameters (for example, bell speed, fluid flow rate, and the like) will be correlated directly to the spray characteristics; which can then be correlated to application characteristics (for example, color, film build, evaporation, transfer efficiency, and the like). For example, the effect on the paint color can be correlated to changes in the spray characteristics (e.g., droplet size, droplet distribution, droplet velocity, and spray pattern or geometry). In the application environment, the optimal spray characteristics can be generated using a calibration procedure to inform a user about how to adjust the spray in order to stay within specifications.

In an example, an operator can indicate the spray characteristics that result in the best color and film build while creating the paint map. Since the effect of each operational parameter in trials specified by design of the experiment is captured by the spray map, if an external parameter affects the spray characteristics (such as temperature, which is a significant concern between warm and cool months), the present system can recommend corrective action. For example, a higher temperature would result in greater evaporation and droplets smaller than an optimal size. Returning to the bell speed example of FIG. 6, the present system can use the spray map to, for example, recommend a particular percentage reduction in bell speed to increase the size of droplets.

Advantageously, the present embodiments provide an approach where color, film build, and transfer efficiency are functions of spray characteristics (e.g., droplet size, droplet distribution, droplet velocity, and/or spray pattern or geometry). While developing the spray map, a correlation of how the droplet size varies due to changing specific operational parameters can be determined, and then a correlation of how these changing parameters affect color, film build, and transfer efficiency can be determined.

The spray map data can be compiled in the database 116, and the system 100 can use such spray maps during production.

In some cases, at block 208, the adjustment module 126 can reference the spray map to determine various adjustments to the operational parameters by comparing the paint film application to a given specification. For example, if the droplet size is smaller than recommended by the specification, the paint color will appear lighter than desired, and the recommendation can be to increase the droplet size by decreasing the bell speed. Advantageously, because the system 100 can use the accurate correlations stored in the spray map, changes to environmental conditions, such as temperature and humidity (which can greatly affect spray characteristics), can be accounted for and corrected quickly using in situ scan measurements of the spray.

Generally, the specifications on the color and film build are set by the respective paint manufacturers. During the creation of the spray map, an operator could enter the specifications and tolerances. The spray map correlates the specifications and tolerances (for example, for color, film build, and transfer efficiency) to the spray characteristics.

In some cases, the spray map can include multilevel optimization based on inputs from the user. For example, if the operator specifies some tolerance on the film thickness and color, the spray map can be used to determine optimal parameters to maximize transfer efficiency while ensuring that the color and film thickness are within specification tolerances.

At block 210, the output module 128 can output the spray map and/or the recommendation to the user interface 108, the network interface 110, and/or the database 116. In some cases, the output module 128 can output the recommendation to the device interface to instruct the application apparatus to change one or more operational parameters as determined in block 208.

Advantageously, the present inventors determined that droplet size and spray pattern or geometry can be accurately correlated with the spray deposition; instead of roughly trying to estimate spray deposition from parameters of application (such as from bell-cup rotation speed). This added accuracy provides substantial cost savings and efficiency gains when implemented in practice.

In an example of the present embodiments used in pharmaceutical applications, the spray characteristics can be controlled by adjusting specific operation parameters; for example, liquid feed rate, concentration, or viscosity. By monitoring the effects of different combinations of these process parameters on the spray characteristics, a response map can be generated by using, for example, a regression analysis. The spray map can account for each operation parameter and be used to recommend to an operator, or automated controller, how to adjust the parameters such that the particle size, which is the critical process parameter, remains within specification.

One example of mapping an operation parameter is correlating a distance from a spray nozzle to a spray pattern or geometry (i.e., relative volume of the spray); and thus, determining an evaporation rate. Evaporation rate is the rate at which the volume decreases decay due to shell formation by solids which impede the diffusion of solvent to the droplet's outer surface. After the spray map is created using the system 100, regression analysis, for example, can be used to recommend an optimal distance from the nozzle where the droplet size does not change, which indicates the completion of particle formation.

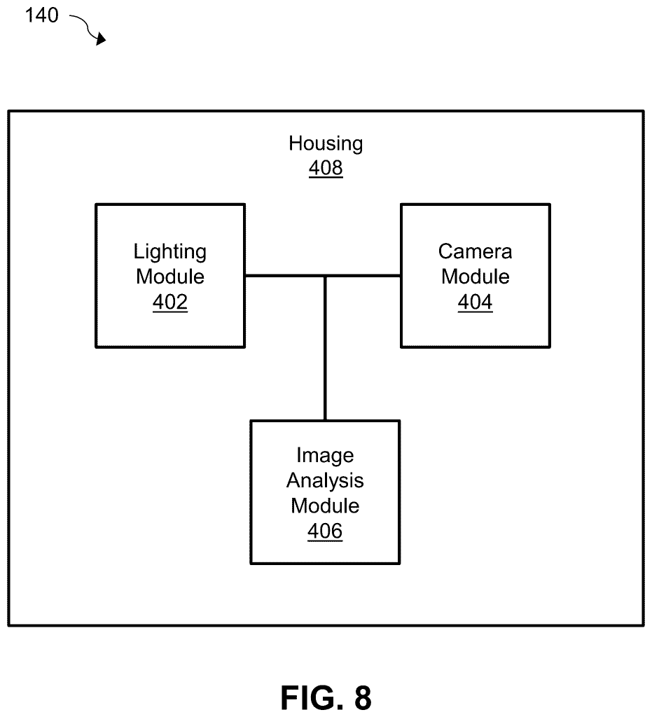

In particular advantageous cases, the imaging device 140, as illustrated in FIG. 8, can include a device for fast-moving particle characterization in order to be able to characterize the droplet size and spray pattern or geometry of the spray in real-time. The device 140 can include a lighting module 402, a camera module 404, and an image analysis module 406. The modules can be interconnected or otherwise in communication using any suitable modality. In some cases, the device 140 further includes a housing 408 to house the camera module 404 and the lighting module 402, and in some cases, also the image analysis module 406. In other cases, the image analysis module 406 can be remote from the housing 408.

While the following disclosure describes performing the functions and operations of the lighting module 402, the camera module 404, and the image analysis module 406 on the device 140, it is understood that one or more of these operations and functions can be performed by the system 100.

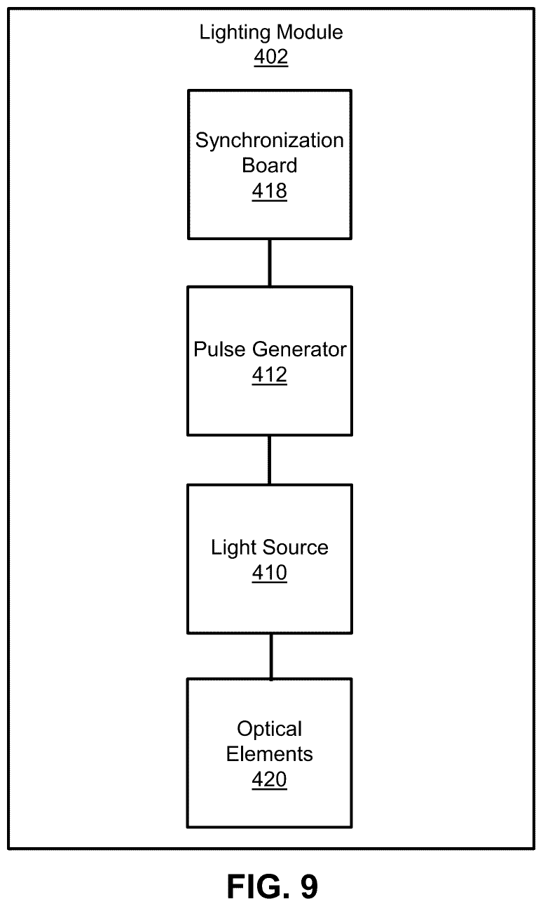

FIG. 9 illustrates an example embodiment of the lighting module 402, which includes a light source 410 (for example, a stacked laser diode array, an light-emitting-diode (LED), a near-infrared (NIR) laser diode, or the like), a pulse generator 412 (otherwise referred to as a current amplifier or function generator), a synchronization board 418, and optical elements 420 to condition the beam. In an embodiment, a laser diode array can be used as the light source 410 because it is bright and compact. In some cases, the light source 410 will include an appropriate driver, such as a laser driver for the laser diode array. In most cases, since a short nanosecond flash is needed to freeze the motion of the particles, light intensity has to be increased high enough to properly illuminate the particles. If the nominal values of the light intensity of a typical laser diode is used, due to its short duration, not enough light energy may be provided to capture the image on a camera sensor. Therefore, the light power must be significantly high for these short duration flashes. To accomplish this, the lighting module 402 includes the pulse generator 412 that can provide current to allow for a high intensity nanosecond flash. In an example, the laser pulse energy can be in the order of 65 uJ and the flash can be on the order of 10 ns-100 ns.

Advantageously, the lighting module 402 can use a high-powered NIR laser diode or LED, as opposed to a lower-power visible wavelength laser. Advantageously, the NIR laser can be more compact than a visible spectrum laser with the same power. There is an inverse relationship between laser power and wavelength. While most other approaches use visible wavelengths, the lighting module 402 can use NIR laser diodes to get a similar brightness on a captured image but with light that better penetrates the spray.

The light produced from the light source 410 can be a combination of beams from each individual diode or LED. For imaging, the beam can be conditioned into a homogeneous flat-top profile of incoherent or semi-coherent light using the optical elements 420. In most cases, the beam should be a flat-top in order to not amplify certain parts of the image, thus making image analysis more accurate. Homogeneous flat top profile generally means that various areas across the laser are the same brightness. Most lasers are naturally brighter in the center of the beam and then get less bright as the distance increases away from the center. For imaging, this property is disadvantageous because even illumination is preferable over every part of the image. If certain portions are illuminated brighter, then it may over-expose that part of the captured image and data can be lost; or if an amplified portion is at the right exposure level, then other portions of the image may be under-exposed and data can be lost. Optical components can be used to create a laser beam that has the same or similar brightness at locations throughout the laser beam; i.e., the profile of the laser is said to be “flat”.

The beam generally is formed of incoherent or semi-coherent light because coherent light generally forms significant diffraction patterns around objects in the image plane, making image analysis more difficult. In examples of the optical elements 420, the beam can be shaped by first passing it through a homogenizing light rod which acts to homogenize and decohere the light. The beam can then be passed through a diffuser to decohere the light further. The beam can then be passed through a device to collimate the light, for example, an aspherical doublet lens. In further cases, a microlens array, a liquid light guide, and a fiber optic cable can be used. It is understood that any suitable approach to make the light less coherent can be used.

The light source 410 can be driven by the pulse generator 412, which receives a trigger signal from the synchronization board 418. The pulse generator 412 can generate high voltage and/or high current pulses with specific durations; for example, as low as one nanosecond. The duration of the light pulse and the parameters of the voltage and current can be controlled using the pulse generator 412, which can receive the trigger signal from the synchronization board 418. The trigger signal is generally generated by the camera module 404, which is passed to the synchronization board 418 to compensate for any noise between the camera module 404 output and lighting module 402. The trigger signal can be an electrical pulse output by the camera used to trigger the light source 410 to operate and illuminate the field of view. In most cases, the trigger signal can be produced by the camera automatically immediately before the camera is set to take an image.

The camera of the camera module 404 outputs a synchronization signal that can be noisy. In some cases, due to such noise, if the synchronization signal was sent directly to the pulse generator 412, then it could cause the light source 410 to falsely trigger. In this way, the synchronization board 418 can be used between the camera module 404 and the pulse generator 412. The synchronization board 412 can, in some cases, accurately detect the camera signal over the background noise and output a noise-reduced signal to the pulse generator 412. The synchronization board 418 can use any suitable noise reduction algorithm.

Once the pulse generator 412 receives the trigger signal from the synchronization board 418, the pulse generator 412 then sends a pulse (in most cases, a high voltage, high current pulse) to the light source 410 that gets converted into light. The connection from the pulse generator 412 to the light source 410 generally has very low inductance. In many cases, to have maximum energy transferred to the light source 410, the pulse generator 412 can be situated close to the light source 410.

Generally, for other approaches, magnification for objective lenses changes with the distance of the captured object. This makes it difficult for a user to calibrate for randomly distributed particles and droplets in space. In order to eliminate the need for such focusing and calibration, the camera module 404 can use a Telecentric lens. Telecentric lenses only accept light perpendicular to the lens surface, thus any object in the field of view stays the same size at any distance within the depth of field. The present inventors conducted example tests to determine a proper combination of (i) camera resolution and pixel size, and (ii) a Telecentric lens with suitable magnification, focal length, and depth of field to capture particles as small as 5 μm. This was able to measure particles down to 5 microns used in hazardous location requirements. In the tests, the resolution ranged from 6-18 MPix, the pixel size ranged from 0.9 um-3 μm, the magnification ranged from 0.5×-3×, and the focal plane distance (working distance) ranged from 100 mm-400 mm.

In some cases, optical power output can be limited to meet hazardous location (Haz Loc) requirements. In such cases, optical power can be lowered below 85 uJ per pulse to ensure the light source 410 is intrinsically safe. Advantageously, camera and lens combination of the camera module 404 is sensitive to low light/power using a telecentric lens with high transmission and low magnification; as well as a camera with physically small pixels to make up for the low magnification lens. This arrangement of the camera module 404 permits the lighting module 402 to use a small, low powered laser. Advantageously, various magnification lenses can be used for the same working distance without requiring the measurement location to change. Lenses with lower magnification are generally physically smaller, making such lenses more compact than other approaches.

The housing 408 advantageously can enclose all of the optical and electronic components. In this way, the user will generally not have to worry about finding correct settings as fixed lighting module 402 and camera module 404 positions allow for simplified measurement procedure. The housing 408 also advantageously protects the components from a mist environment of a spray, or from any other ambient conditions. This property is substantial because it will generally be positioned inline and, in some cases, can be positioned inside a spray or particulate flow. In this environment, the housing 408 can effectively protect the components against moisture. The housing 408 also advantageously isolates the components inside the housing 408 from the outside environment. In some cases, it can operate in a spray environment such as a hazardous location or industrial location, in which there may be a very high explosion danger due to the chemical makeup of the particles. If a spark or small explosion occurs inside the housing, it is essential that it does not cause further ignition or explosions inside the spray environment.

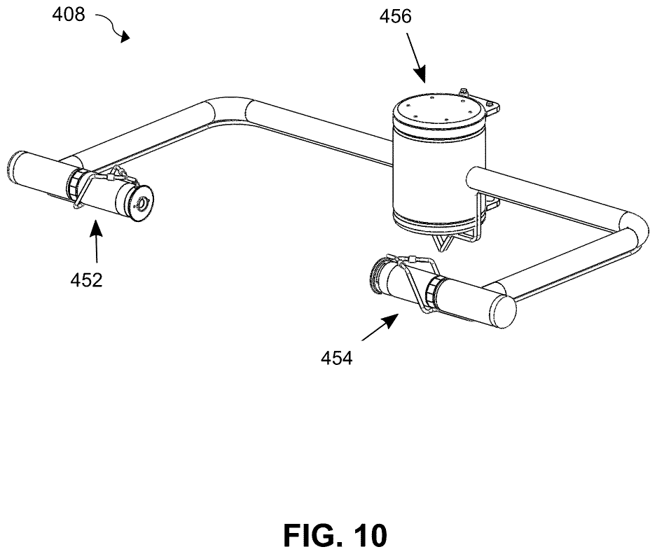

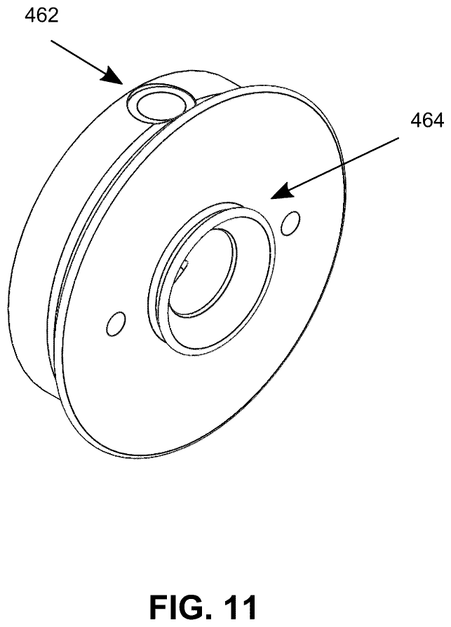

Advantageously, the lighting module 402 allows for a smaller housing 408 and for minimizing the size of the device 140 overall. FIG. 10 illustrates an example embodiment of the housing 408. In this example, a lighting probe 454 of the housing 408 comprising the lighting module 402 can be a cylinder. In this example, a camera probe 452 of the housing 408 comprising the camera module 404 can also be a cylinder. An imaging section 456 of the housing 408 comprising at least the image analysis module 406 can be connected to the camera probe 452 and the lighting probe 454. The housing 408 can include conduits in house the communication channels for communication between the components. It is appreciated that in other examples, any suitable arrangement of the housing and probes can be used. In this example, the housing 408 is made of stainless steel; but in further examples, can be any other suitable material, such as aluminum.

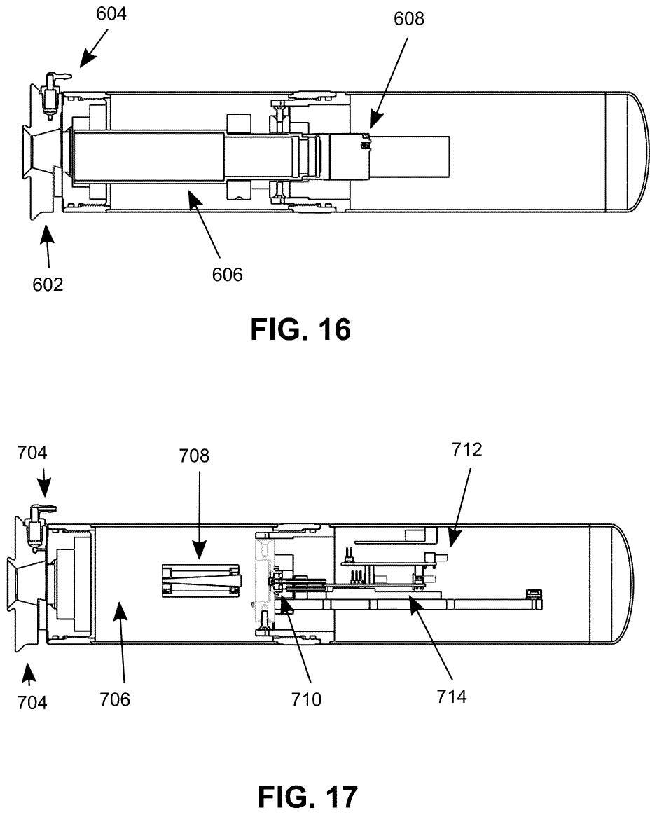

FIG. 16 illustrates a cutaway view of an example of the camera probe 452 and FIG. 17 illustrates a cutaway view of an example of the laser probe 454. In some cases, the lighting probe 454 and the camera probe 452 can each have a front window that forms a dust and liquid tight enclosure. In some cases, in front of the camera probe 452 window, a purge plate can be positioned to prevent build up of particles and debris on the windows.

In this example, the camera probe 452 includes a front cover 602, with a purge inlet 604, a lens assembly 606, and a camera 608. In this example, the laser probe 454 includes a front cover 702, with a purge inlet 704, collimating optics 706, homogenizing optics 708, a laser 710, a synchronization board 712, and a pulse generator 714.

The probes can be fabricated with any suitable materials; for example, aluminum and quartz disc for the window. The glass for the window can be compressed between an internal retaining ring and the body of the probe. Two O-rings can be used to seal each window. One is placed in a groove and compressed on the body of the probe and the other placed in a groove in the window and compressed around the quartz glass. Threaded holes in the body of the window and clearance holes in the body of the probe can be used; for example, where one of such holes carries compressed air towards the window piece which turns the air flow into an air curtain to keep the droplets away from the surface of the glass and keep the viewing area clean.

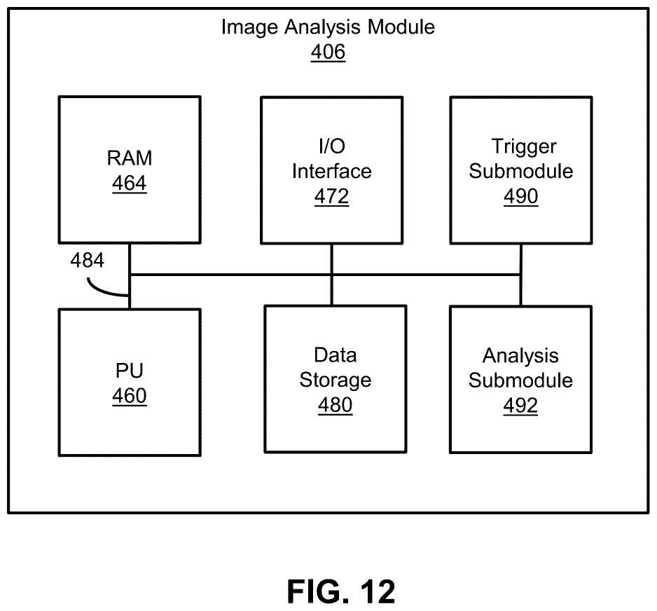

FIG. 12 illustrates a schematic diagram of an example embodiment of the image analysis module 406. In this example, the image analysis module 406 can include a number of physical and logical components, including a processing unit (“PU”) 460, random access memory (“RAM”) 464, an input/output (I/O) interface 472, data storage 480, and a local bus 484 enabling PU 460 to communicate with the other components. PU 460 can include one or more processors; such as in a central processing unit or a graphics processing unit. RAM 464 provides relatively responsive volatile storage to the PU 460. The I/O interface 472 enables a user to provide input via, for example, a keyboard and mouse. The I/O interface 472 can also output information to output devices, for example, a display or speakers. The I/O interface 472 can also permit communication with the other modules and/or other systems or computing devices. Data storage 480 stores the operating system and programs, including computer-executable instructions for image analysis, as well as any derivative or related process. During operation, the operating system, the programs and the data may be retrieved from the data storage 480 and placed in RAM 464 to facilitate execution. In an embodiment, the PU 460 can be configured to execute various conceptual submodules, for example, a trigger submodule 490 and an analysis submodule 492. In further embodiments, the functions of the image analysis module 406 can be executed on dedicated hardware or specific microprocessors, as suitable. In some cases, the I/O interface 472 can comprise a user interface; for example, through a web browser or cloud computing interface, which allows for easier integration with existing systems.

The image analysis module 106 can perform a number of operations; for example, with respect to paint sprays:
performing statistical and visual results to compare various nozzles by:
bringing a nozzle into the field of view of the camera,
capturing images of the droplets from the spray,
determining statistics about the droplet size distribution in real-time,
collecting more data from as many different nozzles or sprays as needed, and
storing the data for comparison in post-processing.
ensuring that there is no damage to the nozzle,
verifying the spray in between cleaning cycles and/or changing of paint color to ensure that the spray characteristics remain unchanged compared to paint/nozzle manufacturer recommendations or facility specifications,
preventing improper painting by ensuring consistency of spray prior to the application of paint, and
ensuring that the spray characteristics remain unchanged compared to paint/nozzle manufacturer recommendations or facility specifications by measuring droplet size properties and statistics, as described above, to ensure that over time the statistics do not change within a certain tolerance.

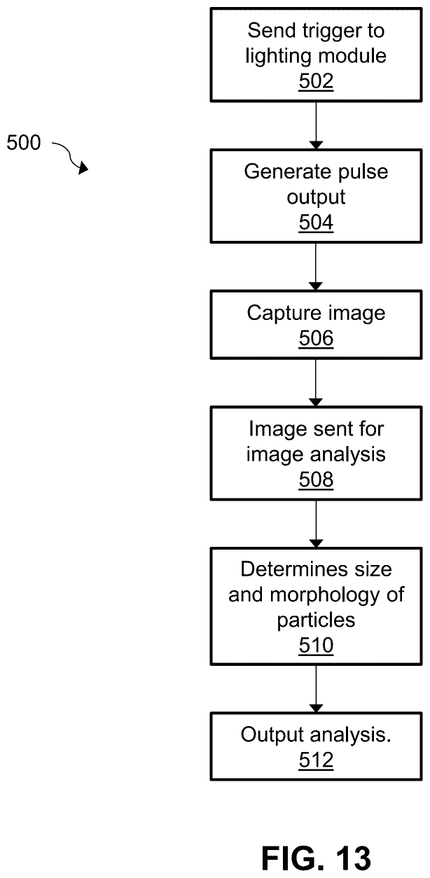

Referring now to FIG. 13, shown therein is a method for fast-moving particle characterization 500, in accordance with an embodiment. The method 500 may be performed when at least some of the spray is located between the lighting probe 454 and the camera probe 452.

At block 502, the trigger submodule 490 or the camera module 404 sends a trigger to the lighting module 402 using, for example, a time-to-live (TTL) trigger output signal.

At block 504, the lighting module 402 generates a pulse output, such as a laser pulse.

At block 506, the camera module 404 captures an image on an image sensor. In some cases, such image can be a shadowgraph image of particles located between the lighting module 402 and the camera module 404.

At block 508, the analysis submodule 492 receives the captured image from the camera module 404.

At block 510, the analysis submodule 492 determines properties of the particles detected in the captured image, such as size and/or morphology, and in some cases, determines statistics based on such properties. Various suitable statistical quantities can be determined from the particle properties, for example, mean, standard deviation, Sauter mean diameter, minimum size, maximum size, number percentiles, volume percentiles, span, and the like.

At block 512, the analysis submodule 492 outputs the analysis. For example, outputting a characterization of the shadowgraph images, size distribution, and statistical quantities to the data storage 480 or to a display or other computing device via the I/O interface 472.

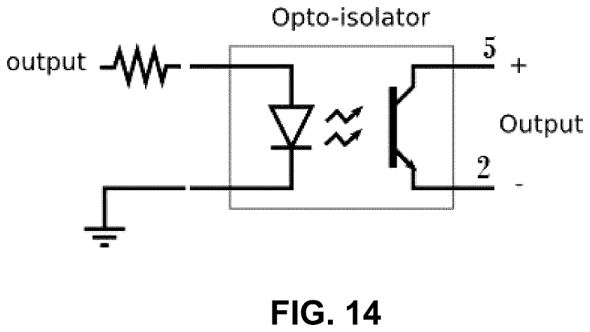

In an example embodiment, the camera module 504 includes an image sensor, an opto-decoupled trigger, a flash as the light source, and two GPIOs (General Purpose Input/Output). The flash outputs can be galvanically isolated using an opto-isolator, as exemplified in the schematic of FIG. 14, to protect the camera module 104 and the image analysis module 406 against surges. The output of the opto-isolator can be used as an open collector or open emitter output; meaning that the output signal can be connected to ground or to the supply voltage. The camera exposure can be synchronized with the light source 410 such that an image can be recorded by the image sensor. The image formed can be a shadowgraph of the particles in a field of view of the image sensor. The shadowgraph produces shadows that are used to identify the morphology of the particles. The morphology can be any geometric information about the particle; including diameter, perimeter, area, aspect ratio, eccentricity, and the like.

Shadowgraphy is a technique of producing and analyzing shadows of an object, rather than the object itself. In shadowgraphy, the light source 410 is located behind the object being imaged and thus the object blocks the light from going into the camera and produces a shadow (darker region) on the camera sensor. The shadows have exactly the same geometry as the object itself, so the object's morphology can be determined by detecting and analyzing the shadows in the image.

In most cases, the image analysis module 406 can consider various factors; for example, (i) whether drops and particles are in focus or out of focus, and how to identify and correct for such effects; (ii) what is the effect of droplet or particle motion on the image quality and measurement; and (iii) how accurately the particle edges are defined. Additionally, the image analysis module 406 can perform image acquisition, image processing, and user interface and data logging automatically. Images captured by the camera module 404 can either be processed by the image analysis module 406 in real-time, or stored in the data storage 480 and later processed.

The parameters for the flash output of the camera module 104 can be set by a user. In some cases, flash output can have two modes, high active and low active. The digital output is set to “High” during the exposure in high active mode. The digital output is set to “Low” during the exposure in low active mode. Flash delay sets the delay for the digital output. After an exposure has started, activating the digital output is delayed by the time set in flash delay. Duration sets the switching time of the digital output. The digital output is activated for the time set in Duration.

In order to capture high-contrast images of the spray of particles, in an example, the flash (for example, an array of light-emitting-diodes (LED)) can trigger for a few hundred nanoseconds. Because of the short exposure time, very high illumination intensities are generally needed. In an example, the flash can comprise a high-power green LED (PT-120 LED drawing 30 A at 5.9 V to drive a maximum luminous flux of 5200). In an example, an LED driver module can be used that allows applying high current (up to 240 A) and voltage (up to 100V) pulses to the LED. The LED driver generates a pulse width of 60 ns to 1 μs. The pulse width can be dictated by the trigger input signal.

In some cases, it may not be possible to trigger the input signal of the LED driver with the flash output signal from the camera module 404 because, generally, the maximum pulse width that can be generated by the camera module 404 is only 40 μs. In order to achieve short controlling pulses, it is possible to use a programmable version of the pulse generator 412.

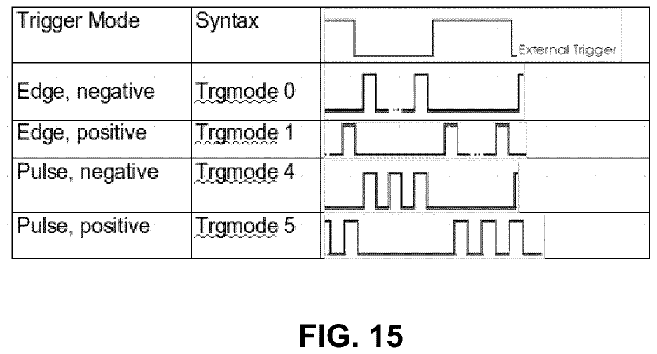

In an example, the pulse generator 412 can have four triggering modes, as illustrated in FIG. 15; however any suitable number or suitable type of triggering can be used. Proper positioning of the flash can be determined by selecting a suitable triggering mode. Triggering modes 1 and 4 (Trgmode 1 and Trgmode 4) can be used if the camera module 104 flash output signal is set on active high. Triggering modes 0 and 5 (Trgmode 0 and Trgmode 5) can be used if the camera module 404 flash output signal is set on active low. The number of generated pulses can be determined by the user via shots syntax.

While the pulse generator 412 is connected to the LED driver, the voltage mode can be active by default and used for calibration to change the mode into the current mode. Uₘᵢₙ is as a minimum value for the voltage (Slightly more than the threshold voltage for the diode, for example, 12V) and Over-Current is a maximum diode current used for calibration. If the error occurs during the calibration it is shown that Uₘᵢₙ need to be increased. When LED is changed, the calibration can be performed again since the pulse generator cannot detect the change. When the calibration is completed, the mode can change automatically to the current mode. The laser diode 110 can be switched on after the current, voltage, repetition rate, triggering mode, shots are adjusted in the current mode using a suitable syntax.

Advantageously, the device 140 can measure particle sizes of down to, for example, 5 microns. In an example, the pulse duration of 10-100 nanoseconds can be generated. In an example, light wavelength was either 532 nm or 905 nm, but can be changed depending on each specific application. Depending on the optics, in an example, the depth field can range from 50 μm to 1 mm.

Advantageously, the device 140 can provide a modular design that allows it to be used in multiple settings and industries. The system 100 allows for easy interchange of certain components for different applications, without changing the function or operating principle of the device 140. For example, the camera can be changed for higher or lower resolution or higher or lower pixel size, or the lens can be changed for higher or lower magnification.

Although the invention has been described with reference to certain specific embodiments, various modifications thereof will be apparent to those skilled in the art without departing from the spirit and scope of the invention as outlined in the claims appended hereto. The entire disclosures of all references recited above are incorporated herein by reference.

1. A processor-executable method for determining spray characteristics of a powder or liquid spray, the method comprising:
receiving spray characteristics of the powder or liquid spray;
generating a spray map comprising correlating the received spray characteristics to spray application characteristics, operational parameters of a spray apparatus, or both, the correlations determined using a calibration of the scanning measurements; and
outputting the spray map.

2. The method of claim 1, further comprising adjusting operational parameters of the spray apparatus to achieve a specific performance of application of the spray using the spray map.

3. The method of claim 1, wherein the spray characteristics comprise one or more of droplet size, droplet distribution, droplet velocity, and spray pattern or geometry.

4. The method of claim 1, wherein the operational parameters comprise one or more of bell speed, flow rate, shaping air flow rates, and electrostatic charges.

5. The method of claim 1, wherein the scanning measurements are conducted at several distinct positions.

6. The method of claim 5, wherein the spray apparatus is moved radially, and wherein generating the spray map comprises determining the spatial position of each droplet as a function of the spray radius using a time at which each captured scan was performed.

7. The method of claim 1, wherein the calibration comprises changing, one or more operational parameters and determining effects on the spray characteristics using the scanning measurements.

8. The method of claim 1, wherein the spray map is generated using a model to correlate the spray characteristics to the operational parameters.

9. The method of claim 1, wherein generating the spray map comprises correlating spray characteristics to changes in operational parameters, and correlating changes in spray characteristics to spray application characteristics.

10. The method of claim 1, wherein the spray application characteristics comprise one or more of color, film build, film appearance and quality, evaporation, powder morphology, and transfer efficiency.

11. A system for determining spray characteristics of a powder or liquid spray, the system comprising one or more processors in communication with a data memory to execute:
a scanning module to receiving spray characteristics of the powder or liquid spray; and
a mapping module to generate a spray map comprising correlating the received spray characteristics to spray application characteristics, operational parameters of a spray apparatus, or both, the correlations determined using a calibration of the scanning measurements, and to output the spray map.

12. The system of claim 11, further comprising an adjustment module to adjust operational parameters of the spray apparatus to achieve a specific performance of application of the spray using the spray map.

13. The system of claim 11, wherein the spray characteristics comprise one or more of droplet size, droplet distribution, droplet velocity, and spray pattern or geometry.

14. The system of claim 11, wherein the operational parameters comprise one or more of bell speed, flow rate, shaping air flow rates, and electrostatic charges.

15. The system of claim 11, wherein the scanning measurements are conducted at several distinct positions.

16. The system of claim 15, wherein the spray apparatus is moved radially, and wherein generating the spray map comprises determining the spatial position of each droplet as a function of the spray radius using a time at which each captured scan was performed.

17. The system of claim 11, wherein the calibration comprises changing, one or more operational parameters and determining effects on the spray characteristics using the scanning measurements.

18. The system of claim 11, wherein the spray map is generated using a model to correlate the spray characteristics to the operational parameters.

19. The system of claim 11, wherein generating the spray map comprises correlating spray characteristics to changes in operational parameters, and correlating changes in spray characteristics to spray application characteristics.

20. The system of claim 11, wherein the spray application characteristics comprise one or more of color, film build, film appearance and quality, evaporation, powder morphology, and transfer efficiency.
